(19) United States
(12) Patent Application Publication
(10) Pub. No.: US 2012/0034764 A1
(43) Pub. Date: Feb. 9, 2012

(54) SYSTEM AND METHOD FOR FABRICATING THIN-FILM PHOTOVOLTAIC DEVICES

(75) Inventors: Piero Sferlazzo, Marblehead, MA (US); Thomas Michael Lampros, Cambridge, NY (US)

(73) Assignee: AVENTA TECHNOLOGIES LLC, Danvers, MA (US)

(21) Appl. No.: 12/850,939

(22) Filed: Aug. 5, 2010

(51) Int. Cl. H01L 21/36; C23C 14/35

(52) U.S. Cl. 438/479; 204/298.16; 204/298.13; 438/62; 257/E21.461

(57) ABSTRACT

Described are an apparatus and a method for depositing a thin film on a web. The method includes depositing a first layer of a composite metal onto a web. A first selenium layer is deposited onto the first layer and the web is heated to selenize the first layer. Subsequently, a second layer of the composite metal is deposited onto the selenized first layer and a second selenium layer is deposited onto the second layer. The web is then heated to selenize the second layer. The composition of each composite metal layer can be varied to achieve desired bandgap gradients and other film properties. Segregation of gallium and indium is substantially reduced or eliminated because each incremental layer is selenized before the next incremental layer is deposited. The method can be implemented in production systems to deposit CIGS films on metal and plastic foils.

### FIELD OF THE INVENTION

The invention relates generally to the manufacture of electronic devices. More particularly, the invention relates to a method and a system for forming photovoltaic light absorbing Chalcopyrite compound layers of copper indium gallium diselenide (CIGS) on metal and plastic foils for fabrication of thin film solar cells and modules.

### BACKGROUND OF THE INVENTION

Thin film solar cells have attracted significant attention and investment in recent years due to the potential for lowering the manufacturing costs of photovoltaic solar panels. Most solar panels are fabricated from crystalline silicon and polycrystalline silicon. While silicon-based technology enables fabrication of high efficiency solar cells (up to 20% efficiency), material costs are high due the embodied energy to refine and grow the bulk silicon ingots of silicon from silicon dioxide. In addition, sawing these ingots into wafers results in approximately 50% of the material being wasted. These solar cells are the primary component of the majority of solar panels made and sold today. Presently, silicon solar cells are approximately 90 μm thick. In contrast, thin film solar cells include layers that are approximately 1 μm an to 3 μm an thick and are deposited directly onto low cost substrates. Among the most popular materials used are amorphous silicon, copper indium diselenide and its alloys with gallium or aluminum (CIS, CIGS, CIAS) and cadmium telluride (CdTe).

Typically amorphous silicon has the lowest manufacturing costs in terms of cost per unit of power produced ($/W), but the efficiencies of the solar cells are generally less than 10% which is low relative to the efficiencies of other materials. CIGS and CdTe cells have higher efficiencies and in the lab have achieved efficiencies approaching and sometime exceeding the efficiencies of silicon-based cells. Small area laboratory-scale cells have demonstrated efficiencies in excess of 20% and 18% for CIGS and CdTe, respectively; however, the transition to volume manufacturing and larger substrates is difficult and substantially lower efficiencies are realized.

Recently, CIGS solar cells have been produced in the laboratory and in production using a three phase co-evaporation process. In this process effusion sources of copper (Cu), indium (In) and gallium (Ga) evaporate at the same at the same time in the presence of a selenium source. In this manner, deposition and selenization occur in a single step as long as the substrate temperature is maintained between about 400° C. and 600° C. Typically, higher temperatures result in higher efficiencies; however, not all substrates are compatible with higher temperatures. Sodium is often added to the mixture of sources and has been shown to enhance minority carriers and to improve voltage. Sodium may also passivate surfaces and grain boundaries. The deposition is repeated three times. For each deposition, the relative concentrations of copper, indium and gallium are changed, thus producing a graded compositional structure that can be more effective at absorbing and converting incident light into electrical power.

Scaling the three phase co-evaporation process to production levels is complicated due to a number of fundamental difficulties. First, effusion sources require high power consumption at production scale because the sources need to be maintained at temperatures as high as 1,500° C. At these high temperatures many materials are extremely reactive. Longevity of system components is decreased and process control and maintenance are difficult. Thus costs associated with production systems are high and downtime can be significant.

The substrate temperature is high during the selenization process. Consequently, the selenium residence time on the substrate surface is small and the selenium utilization efficiency is low. Selenium utilization and unwanted accumulation in various regions of the process chamber make the co-evaporation process difficult to manage in a production environment.

A number of groups have fabricated solar cells using the co-evaporation process while other groups have adopted production-compatible alternatives. One common alternative approach is based on a two-step process that typically includes depositing the metals (copper, indium and gallium) on a substantially cold substrate, that is, near or at ambient temperature. The deposited metals are then selenized in a hydrogen selenide (H₂Se) gas or in a selenium vapor from a solid source. An ambient temperature is maintained between about 250° C. and 600° C.

The metals are typically deposited by electroplating, sputter deposition or printing. The metal deposition step is often followed by a cold deposition of selenium prior to the substrate entering a selenization furnace. The selenium deposition thickness is in the range of approximately 1 μm to 2 μm. By creating a selenium layer on top of the CIG layer, indium is prevented from diffusing out of the metal layer during the ramping of the furnace temperature. The temperature ramp can be of long duration, especially for thick glass substrates; however, for thin flexible foils, rapid temperature ramps (e.g., 10° C./s) are possible and are significant in reducing the problem of indium depletion. This two-step process is more controllable and easier to implement in system equipment in comparison to the co-evaporation technique; however, the resulting efficiencies generally are lower by 2% to 4%. The lower efficiencies are due to non-ideal grain formation and to the segregation of gallium and indium during the selenization step. Typically, gallium diffuses toward the back electrode to form a CuGaSe compound, while indium diffuses toward the barrier layer to form an indium rich compound near the front surface of the cell. Sulfur is sometimes added to the selenium in the furnace to compensate for this diffusion problem by increasing the bandgap of the material at the surface; however, the resulting absorbing layer is not a true CuInGaSe₂ compound and the known advantages of adding gallium to CIS are moderated.

A hybrid technique has been used to implement a co-sputtering/selenization; however, selenium poisoning of the sputtering targets can occur and the hot substrate results in poor selenium utilization. Thus this technique is generally more difficult to control than the co-evaporation process.

### SUMMARY

In one aspect, the invention features an apparatus for deposition of a thin film on a web. The apparatus includes a roll-to-roll substrate transport system to bi-directionally transport a web between two rolls. The apparatus also includes a first sputtering zone and a second sputtering zone. Each sputtering zone has a plurality of magnetrons. In one embodiment, the sputtering zones are configured to deposit a copper indium gallium layer onto the web. A selenization furnace is disposed between the sputtering zones and is configured to maintain a furnace pressure that is greater than a pressure of the sputtering zones. A first selenium trap is disposed between the first sputtering zone and the selenization furnace and a second selenium trap is disposed between the second sputtering zone and the selenization furnace.

In another aspect, the invention features a method of depositing a thin film on a web. The method includes depositing a first layer of a composite metal onto a web and depositing a first selenium layer onto the first layer of the composite metal. The web is heated to selenize the first layer of the composite metal. A second layer of the composite metal is deposited onto the selenized first layer. A second selenium layer is deposited onto the second layer of the composite metal and the web is heated to selenize the second layer of the composite metal. In one embodiment, the composite metal comprises a copper indium gallium composition.

In another aspect, the invention features an apparatus for fabricating a thin film photovoltaic device. The apparatus includes a roll-to-roll substrate transport system, a first and a second sputtering zone, a first and a second cooling roll, a selenization furnace and a first and a second selenium trap. Each of the sputtering zones has a plurality of magnetrons and is configured to deposit a copper indium gallium layer on the web. The first and second cooling rolls are disposed between the first and second sputtering zones. The selenization furnace is disposed between the first and second cooling rolls and is configured to maintain a furnace pressure that is greater than a pressure of the sputtering zones. The first selenium trap is disposed between the first cooling roll and the selenization furnace, and the second selenium trap is disposed between the second cooling roll and the selenization furnace.

### BRIEF DESCRIPTION OF THE DRAWINGS

The above and further advantages of this invention may be better understood by referring to the following description in conjunction with the accompanying drawings, in which like numerals indicate like structural elements and features in the various figures. For clarity, not every element may be labeled in every figure. The drawings are not necessarily to scale, emphasis instead being placed upon illustrating the principles of the invention.

FIG. 1 is an illustration of an embodiment of an apparatus for depositing a copper indium gallium diselenide film on a web according to the invention.

FIG. 2 is a flowchart representation of an embodiment of a method of depositing a copper indium gallium diselenide film on a web according to the invention.

FIG. 3 illustrates a selenization furnace for the apparatus of FIG. 1 that includes three independently controlled heating zones according to an embodiment of the invention.

FIG. 4 is a schematic illustration of a selenium trap for the apparatus of FIG. 1 according to an embodiment of the invention.

### DETAILED DESCRIPTION

The systems and methods of the present invention may include any of the described embodiments or combinations of the described embodiments in an operable manner. In brief overview, the systems and methods of the invention enable the deposition of a CIGS thin film by sputtering deposition on metal and plastic thin foils. The flexibility and bandgap engineering advantages of co-evaporation techniques are realized without the production scaling problems of prior art co-evaporation systems. CIGS devices having high conversion efficiencies are manufactured using a multistep process that includes sputtering and selenization sequences. First, a substantially thin metal layer of CuInGa (e.g., approximately 0.15 μm thickness) is deposited onto a cold web substrate. For example, the web temperature in the sputtering region is preferably as low as practical (e.g., ambient temperature) but may be up to 300° due to operation of the sputtering equipment. Subsequently, selenization occurs in a selenization furnace which is in-line with the sputtering system. The process is repeated a number of times until a desired thickness of the absorber layer is attained (e.g., approximately 2.5 μm). The composition of each incremental thin metal layer can be varied throughout the full deposition process to achieve desired bandgap gradients and other film properties. Segregation of gallium and indium is substantially reduced or eliminated because each incremental layer is selenized before the next incremental layer is deposited. This epitaxial growth process (or layer-by-layer method) by a co-sputtering/selenization process eliminates the problems associated with the presence of selenium in the sputtering chamber. The process can be implemented in a roll-to-roll production system to deposit CIGS films on metal and plastic foils.

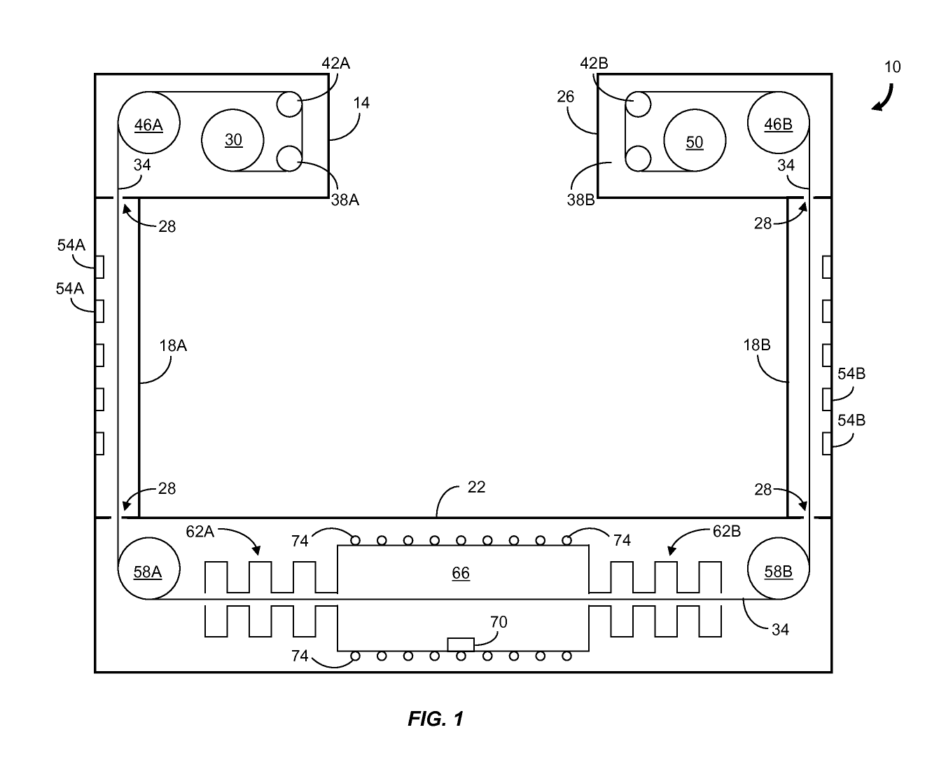

Referring to FIG. 1, an embodiment of an apparatus 10 for deposition of a copper indium gallium diselenide film on a web includes a payout zone 14, a first sputtering zone 18A, a selenization zone 22, a second sputtering zone 18B and a take-up zone 26. As used herein, the term zone means one or more chambers that can be operated to perform a specific process. The sputtering zones 18 and selenization zone 22 are coupled to respective pump systems (not shown) so that the vacuum level for the zones can be independently controlled. Low conductance slits 28 between the zones achieves a high degree of vacuum isolation between neighboring zones.

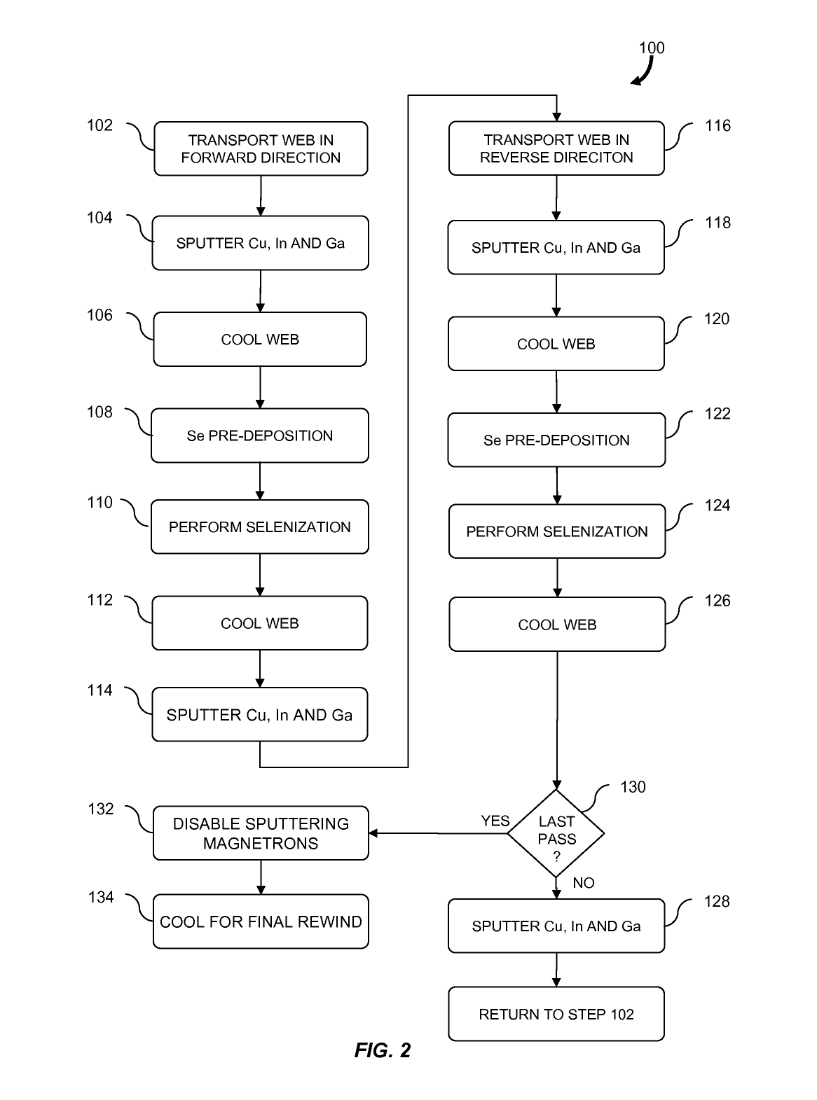

The payout zone 14 includes a payout roll 30 of web material 34, such as a thin plastic or metal foil, that is dispensed and transported through the other zones. The payout zone 14 also includes an idler roll 38A, a load cell 42 to maintain web tension and a cooling roll 46A that has a substantially larger diameter than the other rolls. The take-up zone 26 includes a take-up roll 50 to receive the web 34 after passage through the other zones. The take-up zone also includes rolls 38B, 42B and 46B that function as counterparts to rolls in the payout zone 14. At least one of the payout roll 30 and the take-up roll 50 is coupled to a web transport mechanism as is known in the art that enables the web 34 to pass through the intervening zones. The operation of the payout roll 30 and the take-up roll 50 can be reversed, that is, the payout roll 30 can also perform as a take-up roll and the take-up roll 50 can perform as a payout roll when the web is transported in a reverse direction (right to left) as described below with respect to FIG. 2.

The first sputtering zone 18A is a chamber having a plurality of sputtering magnetrons 54. The magnetrons 54 can be planar magnetrons or rotating cylindrical magnetrons as are known in the art. Target material composition for each magnetron 54 can vary relative to the materials of the targets for the other magnetrons 54 to achieve a graded composition structure in the resulting film.

The selenization zone 22 includes two cooling rolls 58 that surround two differentially pumped selenium traps 62 and a selenization furnace 66 having a selenium source 70. A multiple zone resistive heater comprising heating components 74 enables the furnace temperature along the web path through the selenization furnace 66 to vary.

FIG. 2 shows a flowchart representation of an embodiment of a method 100 of depositing a copper indium gallium diselenide film on a web according to the invention. Referring to FIG. 1 and FIG. 2, the web 34 is transported (step 102) from the payout zone 14 into the first sputtering zone 18A where the pressure is maintained below 0.01 Torr. During passage through the sputtering zone 18A, a deposition (step 104) of an incremental layer of copper, indium and gallium occurs. The targets of each magnetron 54 can have a variety of compositions. For example, each target material can be copper indium gallium, copper gallium or copper indium. The thickness of the incremental layer deposited on the web 34 during passage through the sputtering zone 18A varies according to different process parameters such as the web transport speed. By way of example, the thickness of the deposited incremental layer can be between 100 Å and 2000 Å.

After the first incremental layer is deposited, the web 34 enters the selenization zone 22. The web 34 first passes over a cooling roll 58A to cool (step 106) the web 34 before it enters a multistage differentially pumped selenium trap 62A. The trap 62A prevents selenium that may escape from the selenization furnace 66 from entering the sputtering zone 18A. The web 34 is pre-coated (step 108) with a thin layer (e.g., approximately 0.5 μm) of selenium in the trap 62A before entering the furnace 66. The relatively cold web temperature (e.g., less than 150° C.) allows selenium to condense on the web 34 as it moves through the trap 62. The web 34 then moves through the furnace 66 where selenization occurs (step 110) at a pressure that is substantially higher than the sputter pressure and at a temperature between 250° C. and 600° C. For example, the selenization can occur at a pressure in a range between 0.0001 Torr and 10 Torr. The pre-coating of selenium is advantageous in preventing indium depletion when the web temperature increases rapidly inside the furnace 66.

After exiting the furnace 66, the web 34 is cooled (step 112) to a lower temperature (e.g., less than 100° C.) by a second cooling roll 58B. The web 34 then passes through the second sputtering zone 18A where a second incremental layer of copper indium gallium of varying composition is deposited (step 114).

Once most of the web material from the payout roll 30 has been processed by transport in the forward direction, that is, dispensed from the payout roll 30 through the intervening zones and accumulated onto the payout roll 50, the deposition method 100 continues by transporting the web 34 in the reverse direction (step 116). While the web 34 moves back through the intervening zones, the original payout zone 14 functions as a take-up zone and the original take-up zone 26 functions as a payout zone. The web 34 passes through the sputtering and selenization zones 18 and 22 in reverse order to execute a sequence of steps (steps 118 to 128) that is reversed to the sequence of steps used during the forward transport. Thus a third incremental layer of copper indium gallium is deposited (step 118) on top of the second incremental layer in the second sputtering zone 18B before the second selenium pre-deposition occurs (step 122). Selenization is performed (step 124) during passage through the furnace 66 before a fourth incremental layer of copper indium gallium (step 128) is deposited onto the web 34.

Except for the first pass of the web 34 through the first sputtering zone 18A, it can be seen that selenization is performed after two consecutive passes of the web 34 through the same sputtering zone 18A or 18B. Thus two incremental layers are formed on the web 34 before selenization is performed. Advantageously, in some embodiments the power densities for the sputtering magnetrons can be reduced relative to the power densities for a single pass deposition of an incremental layer prior to selenization. In addition, because the power densities can be changed between passes, the composition of each layer can be changed without the need to change targets.

Forward and reverse transport processing are repeated a number of times until a CuInGaSe₂ film of a desired total thickness is deposited onto the web 34 (as determined at step 130). It should be noted that at the end of the process, the magnetrons in the sputtering zone 18A or 18B used after the last passage through the selenization furnace 66 are disabled (step 132) and the web 34 is cooled before a final rewind (step 134).

The iterative selenization implemented throughout the process reduces or eliminates the gallium and indium segregation problem that is common to two-step CIG processes because the first incremental layer and the pairs of consecutive incremental layers from round-trip passage through a sputtering zone 18 are selenized before the next pair of incremental layers is deposited. Moreover, because the layers to be selenized are thin, the time required for the web 34 to pass through the selenization furnace 66 can be short. Consequently, the web transport speed can be high. The multiple pass forward and reverse process and high web transport speed permit efficient construction of a multilayer structure having a varying composition and bandgap.

Although the apparatus 10 and method 100 described above relate primarily to a configuration having a single selenization furnace 66 and a pair of sputtering zones 18, it should be recognized that other configurations are contemplated according to principles of the invention. For example, multiple selenization furnaces and additional sputtering zones can be employed to enable multiple layers to be deposited and subsequently selenized while the web is transported in a single direction.

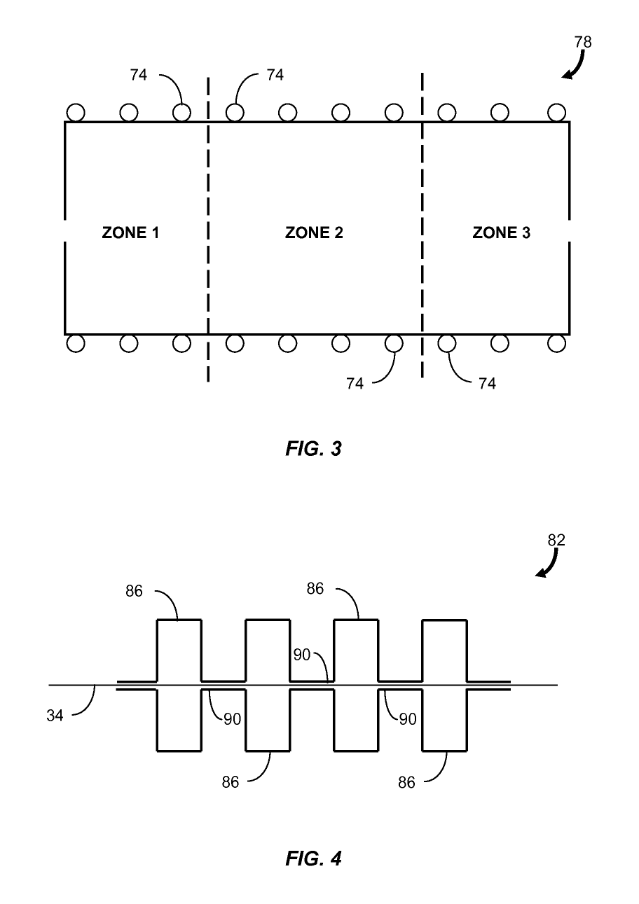

In some embodiments the selenization furnace 66 has multiple heating zones. FIG. 3 shows a selenization furnace 78 having three independently controlled heating zones. For example, ZONE 1 has a higher power density than ZONE 2 and ZONE 3 when the web 34 is transported from left to right in the figure. Conversely, ZONE 3 has a higher power density than the other zones when the web 34 moves in the opposite direction, that is, from right to left. By varying the temperature of the zones in this manner, a more rapid heating of the web 34 occurs as it enters the furnace 78. In some embodiments, the set temperature for the furnace 78 varies for each pass.

Various types of selenium traps can be used. For example, different schemes based on differential pumping to gradually transition from a higher pressure region to a lower pressure region as are known in the art can be used.

FIG. 4 is a schematic representation of an embodiment of a selenium trap 82 according to the invention. The trap 82 includes alternating plenums 86 and narrow gaps 90 of low conductance. The plenums 86 are maintained at a low temperature, for example, at a temperature between 0° C. and 20° C., while the gaps 90 are maintained at a substantially higher temperature, for example, 200° C. or greater. During operation, selenium does not accumulate on the hot surfaces of the gaps 90 but does accumulate on the cold surfaces of the plenums 86. In a preferred embodiment, the selenium pressure is reduced by a factor between approximately 5 and 10 for each gap 90 and neighboring plenum 86 with increasing distance from the selenization furnace 66. The numbers of gaps 90 and plenums 86 are preferentially determined by the desired pressure differential.

While the invention has been shown and described with reference to specific embodiments, it should be understood by those skilled in the art that various changes in form and detail may be made therein without departing from the spirit and scope of the invention as recited in the accompanying claims.

What is claimed is:

1. An apparatus for depositing a thin film on a web, comprising:
a roll-to-roll substrate transport system to bi-directionally transport a web between two rolls;
a first sputtering zone having a plurality of magnetrons;
a second sputtering zone having a plurality of magnetrons;
a selenization furnace disposed between the first and second sputtering zones and configured to maintain a furnace pressure that is greater than a pressure of the first and second sputtering zones;
a first selenium trap disposed between the first sputtering zone and the selenization furnace; and
a second selenium trap disposed between the second sputtering zone and the selenization furnace.

2. The apparatus of claim 1 wherein the selenization furnace is configured to maintain a temperature in a range of approximately 250° C. to 600° C.

3. The apparatus of claim 1 wherein each of the sputtering zones is configured to deposit a copper indium gallium layer on the web.

4. The apparatus of claim 1 wherein the first and second selenium traps are differentially pumped.

5. The apparatus of claim 1 wherein the selenization furnace has a heater comprising a plurality of zones each having a temperature that is independently controlled.

6. The apparatus of claim 1 further comprising a target material for each of the magnetrons, each of the target materials having a composition comprising one of copper indium gallium, copper gallium and copper indium.

7. The apparatus of claim 6 wherein the target material for each magnetron in one of the sputtering zones has a composition that is different from a composition of the target material for each of the other magnetrons in the sputtering zone.

8. The apparatus of claim 1 wherein the web comprises a metal foil.

9. The apparatus of claim 1 wherein the web comprises a plastic foil.

10. The apparatus of claim 1 wherein the magnetrons comprise planar magnetrons.

11. The apparatus of claim 1 wherein the magnetrons comprise rotating cylindrical magnetrons.

12. The apparatus of claim 1 further comprising:
a first low conductance slit disposed between the first sputtering zone and the first selenium trap; and
a second low conductance slit disposed between the second sputtering zone and the second selenium trap.

13. The apparatus of claim 1 further comprising:
a first cooling roll disposed between the first sputtering zone and the first selenium trap; and
a second cooling roll disposed between the second sputtering zone and the second selenium trap.

14. A method of depositing a thin film on a web, the method comprising:
depositing a first layer of a composite metal onto a web;
depositing a first selenium layer onto the first layer of the composite metal;
heating the web to selenize the first layer of the composite metal;
depositing a second layer of the composite metal onto the selenized first layer;
depositing a second selenium layer onto the second layer of the composite metal; and
heating the web to selenize the second layer of the composite metal.

15. The method of claim 14 wherein the second layer of the composite metal comprises a first incremental layer and a second incremental layer deposited after the first incremental layer, and wherein the second selenium layer is deposited onto the second incremental layer.

16. The method of claim 15 wherein a direction of transport of the web is reversed after a deposition of the first incremental layer and before a deposition of the second incremental layer.

17. The method of claim 14 wherein the composite metal comprises a copper indium gallium composition.

18. The method of claim 17 wherein a relative composition of copper, indium and gallium in at least one of the first and second layers of the composite metal varies according to a depth of the layer.

19. The method of claim 17 wherein a relative composition of copper, indium and gallium in the first layer of the composite metal is different from a relative composition of copper, indium and gallium in the second layer of the composite metal.

20. The method of claim 14 wherein the steps of heating the web further comprise applying heat to the web at a varying rate to selenize the respective layer of the composite metal.

21. The method of claim 14 further comprising, after the steps of heating the web, cooling the web prior to depositing the respective selenium layer.

22. An apparatus for fabricating a thin film photovoltaic device, comprising:
a roll-to-roll substrate transport system to bi-directionally transport a web between two rolls;
a first sputtering zone having a plurality of magnetrons and configured to deposit a copper indium gallium layer on the web;
a second sputtering zone having a plurality of magnetrons and configured to deposit a copper indium gallium selenide layer on the web;
a first cooling roll and a second cooling roll each disposed between the first and second sputtering zones;
a selenization furnace disposed between the first and second cooling rolls and configured to maintain a furnace pressure that is greater than a pressure of the first and second sputtering zones;
a first selenium trap disposed between the first cooling roll and the selenization furnace; and
a second selenium trap disposed between the second cooling roll and the selenization furnace.
